(19) United States
(12) Patent Application Publication
(10) Pub. No.: US 2005/0252452 A1
(43) Pub. Date: Nov. 17, 2005

(54) Polynuclear metal molecular beam apparatus

(76) Inventors: Toshiyuki Fujimoto, Tsukuba-shi (JP); Shingo Ichimura, Tsukuba-shi (JP); Hidehiko Nonaka, Tsukuba-shi (JP); Akira Kurokawa, Tsukuba-shi (JP)

Correspondence Address: BIRCH STEWART KOLASCH & BIRCH, PO BOX 747, FALLS CHURCH, VA, 22040-0747, US

(21) Appl. No.: 10/512,091

(22) PCT Filed: Apr. 23, 2003
(86) PCT No.: PCT/JP03/05145

§ 371 Date: Oct. 21, 2004

(30) Foreign Application Priority Data
Apr. 23, 2002 (JP) 2002-120091

(51) Int. Cl. C23C 16/00

(52) U.S. Cl. 118/723 CB

(57) ABSTRACT

A multi-nuclear metal molecular beam apparatus, wherein an ion beam is generated by using a multi-nuclear metal molecule.

### TECHNICAL FIELD

The present invention relates to a multi-nuclear metal molecular beam apparatus that can be used in ultra-precision machining or modification of a substrate (a board), by using a multi-nuclear metal molecule, such as a metal cluster complex, which is chemically stable.

### BACKGROUND ART

In horizontal etching or the like, a cluster ion beam apparatus is used to ultra-precisely machine a substrate, by using the excellent characteristics of cluster. However, in a conventional known cluster beam source, for example, as described in JP-A-2000-38257 (“JP-A” means unexamined published Japanese patent application) and JP-A-2001-158956, use of a chemically-unstable noble gas cluster makes it difficult to obtain a stable beam.

Further, in a conventional cluster ion beam apparatus used to deposit cluster on a substrate to prepare a thin film, collision and association of atoms vaporized in an inert gas atmosphere are used. For this reason, it is difficult to make the size of cluster molecule uniform.

Further, the apparatus for generating cluster is disadvantageously large in scale or complicated.

### SUMMARY OF THE INVENTION

The present invention resides in a multi-nuclear metal molecular beam apparatus, which generates an ion beam by using a multi-nuclear metal molecule.

Further, the present invention resides in a multi-nuclear metal molecular beam apparatus, which comprises: vaporization means for a multi-nuclear metal molecule; ionization means; acceleration means; convergence means; and scanning means.

Other and further features and advantages of the invention will appear more fully from the following description, taken in connection with the accompanying drawings.

### BRIEF DESCRIPTION OF DRAWINGS

FIG. 1 is a front view of a first embodiment of the present invention, explaining the state in which a multi-nuclear metal molecule having a vapor pressure is ionized.

FIG. 2 is an enlarged view of an ionization chamber shown in FIG. 1, explaining the state in which the multi-nuclear metal molecule is ionized by electron impact.

FIGS. 3(a) to 3(c) are views explaining acceleration, convergence, and scanning states of the ionized multi-nuclear metal molecule, respectively.

FIG. 4 is a view explaining the state in which the multi-nuclear metal molecule is ionized by light irradiation.

FIG. 5 is a front view of a second embodiment of the present invention, explaining the state in which a multi-nuclear metal molecule having no vapor pressure is ionized.

FIG. 6 is an enlarged view of an ionization chamber shown in FIG. 5.

FIG. 7(a) is a front view of a third embodiment of the present invention; and FIG. 7(b) is a view explaining the state in which mist of a multi-nuclear metal molecule having no vapor pressure is given electric charge to be ionized, in the third embodiment of the present invention.

FIG. 8 is a front view of a fourth embodiment of the present invention, explaining the state in which a multi-nuclear metal molecule that is hardly soluble and that has no vapor pressure, or a multi-nuclear metal molecule having a low vapor pressure, is vaporized and simultaneously ionized.

FIG. 9 is a graph showing a mass spectrometry result of a multi-nuclear metal molecular ion.

### DISCLOSURE OF THE INVENTION

According to the present invention, there are provided the following means.

(1) A multi-nuclear metal molecular beam apparatus, which generates an ion beam by using a multi-nuclear metal molecule.

(2) The multi-nuclear metal molecular beam apparatus described in item (1), wherein the multi-nuclear metal molecule that is vaporized or atomized, is ionized.

(3) The multi-nuclear metal molecular beam apparatus described in item (2), wherein the multi-nuclear metal molecule that is vaporized or atomized, is ionized by electron impact.

(4) The multi-nuclear metal molecular beam apparatus described in item (2), wherein the multi-nuclear metal molecule that is vaporized or atomized, is ionized by light irradiation.

(5) The multi-nuclear metal molecular beam apparatus described in item (2), wherein the multi-nuclear metal molecule that is vaporized or atomized, is ionized by plasma.

(6) The multi-nuclear metal molecular beam apparatus described in item (2), wherein the multi-nuclear metal molecule that is vaporized or atomized, is ionized by an electric field.

(7) The multi-nuclear metal molecular beam apparatus described in item (2), wherein the multi-nuclear metal molecule that is vaporized or atomized, is ionized by electric charge exchange of highly-excited electrons.

(8) The multi-nuclear metal molecular beam apparatus described in item (1), wherein the multi-nuclear metal molecule is vaporized and simultaneously ionized.

(9) The multi-nuclear metal molecular beam apparatus described in item (8), wherein the multi-nuclear metal molecule is ionized by laser ablation.

(10) The multi-nuclear metal molecular beam apparatus described in any one of items (1) to (7), wherein the multi-nuclear metal molecule is dissolved in a solvent and generated as mist, and the mist of the multi-nuclear metal molecule is given an electric charge, to be ionized.

(11) A multi-nuclear metal molecular beam apparatus, comprising:
vaporization means of a multi-nuclear metal molecule;
ionization means;
acceleration means;
convergence means; and
scanning means.

Herein, the term “multi-nuclear metal molecule” means a compound that can be synthesized by a chemical reaction, that contains a plurality of metal atoms in the molecule, and that can be isolated. Typical examples of the multi-nuclear metal molecule include metal cluster complexes, ligand-stabilized metal clusters, such as Au₅₅[P(C₆H₅)₃]₁₂Cl₆, or the like.

### BEST MODE FOR CARRYING OUT THE INVENTION

One preferable embodiment of the present invention will be described below, with reference to the accompanying drawings. Herein, the same reference numeral is given to the same part or member in the description of the drawings.

### First Embodiment

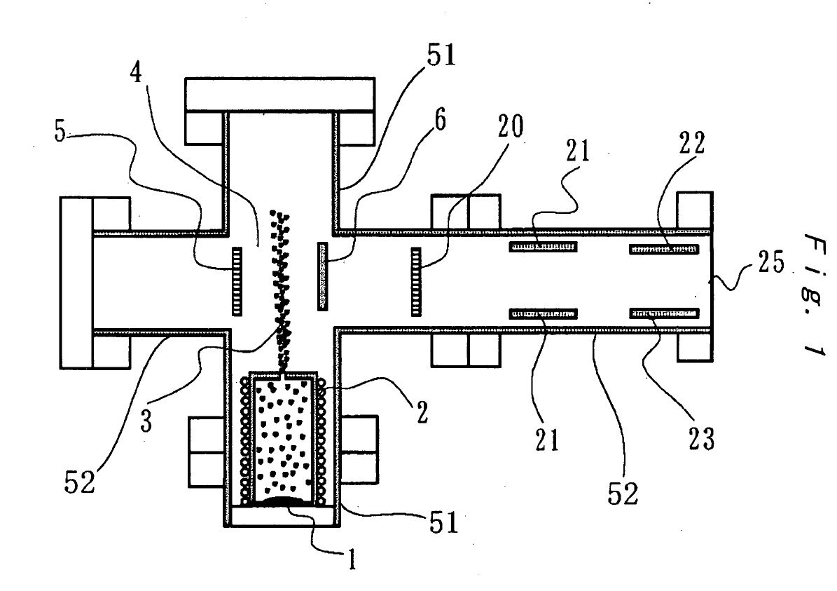

FIG. 1 shows the first embodiment of the present invention. This is an example, in which the present invention is applied to a multi-nuclear metal molecule, such as Rh₄(CO)₁₂, having a vapor pressure.

The molecular beam apparatus, as shown in FIG. 1, has a structure in which a pipe 51 to be used in vaporization of the multi-nuclear metal molecule and a pipe 52 being along a generation direction of a molecular beam cross each other. A small crucible 2 is set at an end portion of the pipe 51, and the multi-nuclear metal molecule 1 is filled in the small crucible 2. In the pipe 52, an acceleration electrode 20, a convergence electrode 21, and scanning electrodes 22 and 23 are provided. One end of the pipe 52 is open as a beam outlet 25. An ionization chamber 4 is formed at the crossing portion of the pipe 51 and the pipe 52. In the ionization chamber 4, the multi-nuclear metal molecule 1 is ionized by any of various ionization means, such as electron impact, light irradiation, plasma ionization (plasma ionization by discharge, or plasma ionization using no discharge phenomenon), an electric field, and charge transfer. The configuration of the ionization chamber 4 is not particularly limited, and is appropriately selected according to the above various ionization means. The apparatus shown in FIG. 1 is the case when electron impact is used as the ionization means. In the ionization chamber 4, a filament 5 and a counter electrode 6 are provided.

When the ionization means is plasma ionization, for example, an electric field is applied to gas molecules having a proper pressure, to cause discharge, thereby generating plasma. The multi-nuclear metal molecule is ionized, by passing (transmitting) it through the plasma. Alternately, a solid of multi-nuclear metal molecule may be irradiated with the plasma generated by glow discharge, to simultaneously vaporize and ionize the multi-nuclear metal molecule. Further, the plasma generation method is not limited to the above methods, and a plasma generation method (for example, ECR plasma: plasma generated by induction heating with electromagnetic wave), which does not use discharge phenomenon, may be used.

When the ionization means is an electric field, a high electric field is applied to the multi-nuclear metal molecule, to achieve ionization. As is observed by an FEM (field emission microscope) or an FIM (field ion microscope), a target material (i.e. a solid of multi-nuclear metal molecule in the present invention) may be sharply acuminated; and a high voltage may be applied across the material and the counter electrode, to concentrate the electric field on the tip end, to vaporize and ionize the multi-nuclear metal molecule at once.

A case in which the ionization means is light irradiation will be described in the second embodiment to be described later. A case in which the ionization means is charge transfer (for example, charge exchange of highly excited electrons) will be described in the third embodiment to be described later.

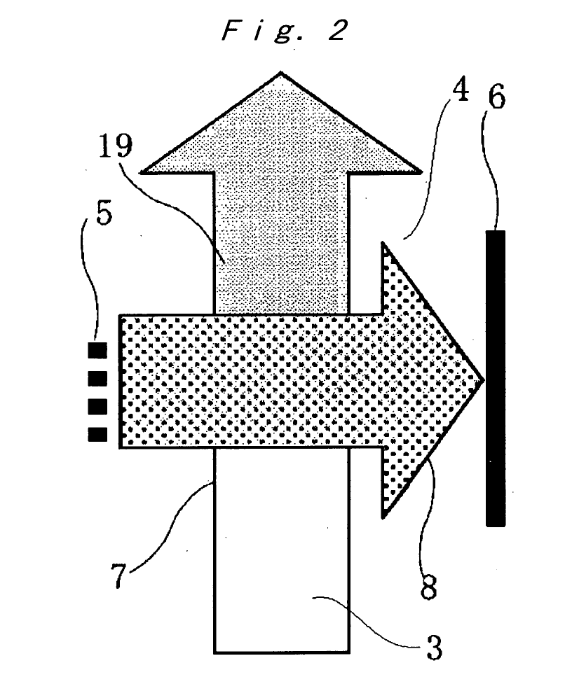

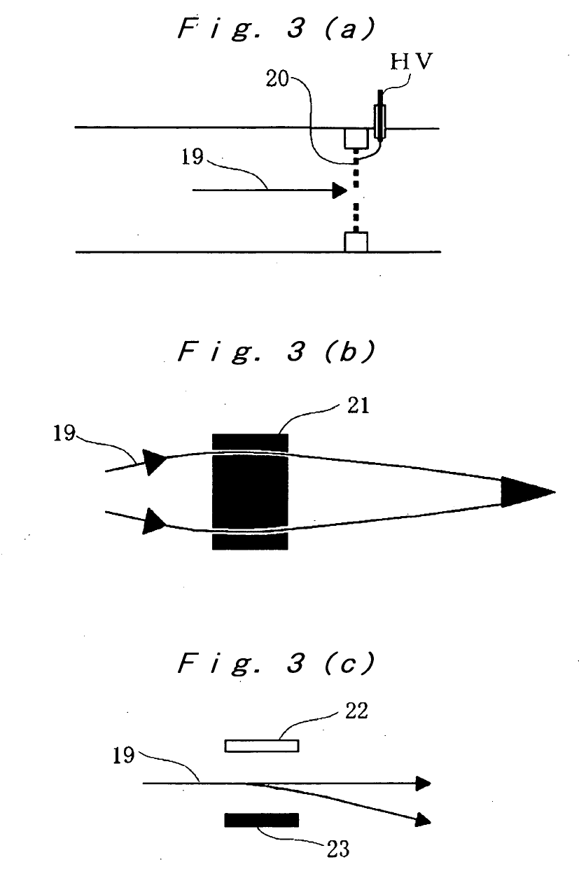

Next, an operation of the first embodiment of the present invention will be described below with reference to FIG. 1, FIG. 2, and FIGS. 3(a) to 3(c). The temperature of the small crucible 2 is raised, to transform the multi-nuclear metal molecule 1 filled in the small crucible 2 into a multi-nuclear metal molecule vapor 3. At this time, the temperature is precisely controlled to keep a constant temperature, thereby uniform multi-nuclear metal molecule vapor 3 can be obtained. Although any of different temperatures may be set at this time depending on the type of the multi-nuclear metal molecule, the temperature is generally set at 30° C. to 200° C., preferably 60° C. to 130° C. The vaporized multi-nuclear metal molecule rises from the top of the small crucible 2 and moves into the ionization chamber 4. In the ionization chamber 4, the multi-nuclear metal molecule is ionized by electron impact.

FIG. 2 is an enlarged view of the ionization chamber 4 shown in FIG. 1, explaining the state of the multi-nuclear metal molecule to be ionized by electron impact. In the ionization chamber 4 shown in FIG. 2, the filament 5, which generates hot electrons in the power-on state, and the counter electrode 6 are provided. Although the material of the filament 5 is not particularly limited, examples of the material to be used include tungsten or the like. Further, although the material of the counter electrode 6 is not particularly limited, examples of the material to be used include tantalum or the like.

In FIG. 2, the hot electrons generated by conducting electricity to the filament 5, are accelerated in the direction of an arrow 8 by a voltage (approximately several tens to 100 V) applied to the counter electrode 6, and then they collide with the multi-nuclear metal molecule vapor 3 which is rising in the direction of an arrow 7. The collision of the electrons having energy ionizes the multi-nuclear metal molecule 3 (reference numeral 19 in the figure denotes the ionized multi-nuclear metal molecule).

FIGS. 3(a) to 3(c) each are a view explaining the flow of multi-nuclear metal molecular ion in the pipe 52. A flow 19 of the ionized multi-nuclear metal molecule, as shown in FIG. 3(a), is accelerated in the direction of an arrow by an electric field that is produced by the acceleration electrode 20 composed of tantalum or the like and applied with a voltage of several hundred volts to several kilovolts having electric charge opposite to that of the ionized multi-nuclear metal molecule 19. The thus-accelerated multi-nuclear metal molecule moves toward the outlet 25, as shown in FIG. 1. In FIG. 3(a), a reference symbol HV denotes a portion to which a high voltage is applied.

The orbit of the accelerated multi-nuclear metal molecular ion 19, as shown in FIG. 3(b), is made to be curved by an electric field that is produced by the convergence electrodes 21 applied with a voltage having the same charge as that of the multi-nuclear metal molecular ion, thereby the flow of multi-nuclear metal molecular ion 19 is converged. As such a voltage applied to the convergence electrodes 21 is high, the orbit is curved sharply. For this reason, the size and shape of the resultant beam can be controlled, by controlling the voltage to be applied.

The orbit of the beam of the accelerated and converged multi-nuclear metal molecular ion 19, as shown in FIG. 3(c), is made to be curved by an electric field, which is produced by the scanning electrode 22 applied with a voltage of the same charge as that of the multi-nuclear metal molecular ion and the scanning electrode 23 applied with a voltage opposite to the charge of the multi-nuclear metal molecular ion. In this case, scanning of the multi-nuclear metal molecular ion beam can be controlled by controlling the strength of the electric field. When a high kinetic energy is given to the multi-nuclear metal molecular ion 19, a beam that can work a substrate by etching, can be achieved. Alternately, when a low kinetic energy is given to the multi-nuclear metal molecular ion 19, a beam that can perform deposition on a substrate surface, can be achieved.

### Second Embodiment

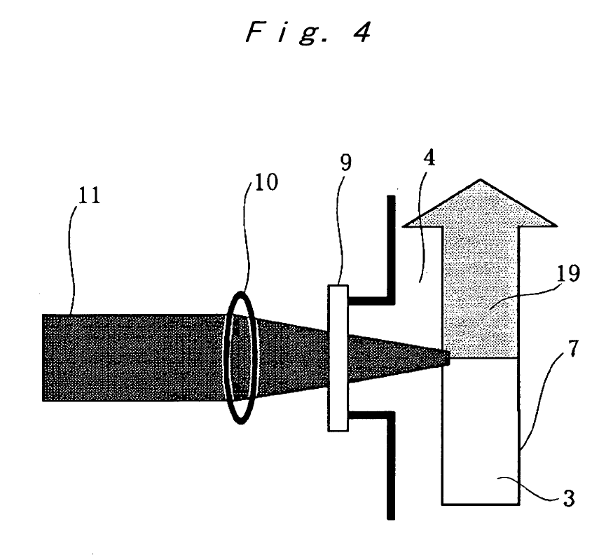

Next, a case in which the ionization means is light irradiation will be described below. FIG. 4 is an enlarged view of an ionization chamber 4, explaining the state in which a multi-nuclear metal molecule is ionized by light irradiation. In the ionization chamber 4 shown in FIG. 4, a window 9 is formed, and irradiation of light 11 converged by a convergent lens 10 is made via the window 9. The material of the window 9 is not particularly limited. As the material, any material which transmits the light 11 may be used. For example, synthetic quartz or the like may be used. A light source of the light 11 is not particularly limited. As the light source, any light source, which can ionize a multi-nuclear metal molecule by light irradiation, may be used. For example, preferable examples to be used include excimer laser or the like.

In FIG. 4, by irradiating the light 11 to the multi-nuclear metal molecule vapor 3 which is rising in the direction of an arrow 7, the multi-nuclear metal molecule 3 is ionized by single-photon- or multi-photon-ionization (reference numeral 19 in the figure denotes the ionized multi-nuclear metal molecule).

Other configurations, operations and effects of the molecular beam apparatus according to this embodiment are almost the same as those of the molecular beam apparatus according to the first embodiment, and the description thereof is omitted.

### Third Embodiment

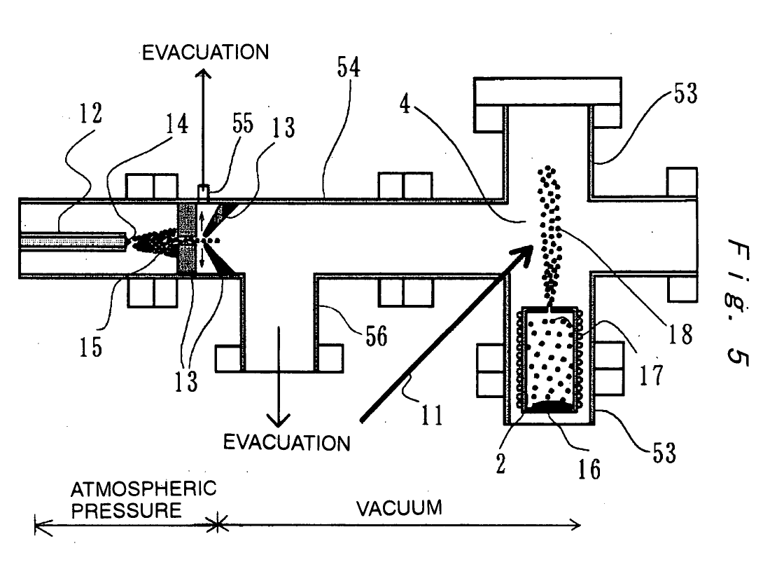

FIG. 5 shows the third embodiment of the present invention, and shows an example in which the present invention is applied to a multi-nuclear metal molecule having no vapor pressure, such as [N(CH₂CH₃)₄]₂[Pt₁₂(CO)₂₄]. Further, this embodiment can also be applied to a multi-nuclear metal molecule having a vapor pressure.

The molecular beam apparatus shown in FIG. 5 ionizes the multi-nuclear metal molecule, by using charge exchange of highly excited electrons (Rydberg electrons); and it has a structure, in which a pipe 53 to be used for generating highly excited electrons and the pipe 54 being along a generation direction of a molecular beam, cross each other. A small crucible 2 is provided at an end of the pipe 53, and a highly-excited-electron-generation material 16 is filled in the small crucible 2. As a highly-excited-electron-generation material 16, for example, cesium can be mentioned. A capillary 12 is provided at an end of the pipe 54, and a multi-nuclear metal molecule solution is put into the capillary 12. A skimmer 13 is provided near an outlet portion 14 of the capillary 12. The pipe 54 has evacuate pipes 55 and 56 provided thereon. A gas is evacuated from the pipes 55 and 56, to perform differential evacuation from the skimmer 13, thereby mist 15 of the multi-nuclear metal molecule solution is generated from the capillary outlet 14. A part where the capillary 12 is provided in the pipe 54 is set in an atmospheric-pressure state. A part extending from the position where the skimmer 13 is provided to the beam outlet is set in a high vacuum state. An ionization chamber 4 corresponds to a portion where the pipe 53 and the pipe 54 cross each other. In this ionization chamber 4, the multi-nuclear metal molecule 1 is ionized, by charge transfer. Although not shown, a structure (the acceleration electrode, the convergence electrode, and the scanning electrode) near the beam outlet is the same as that in FIG. 1.

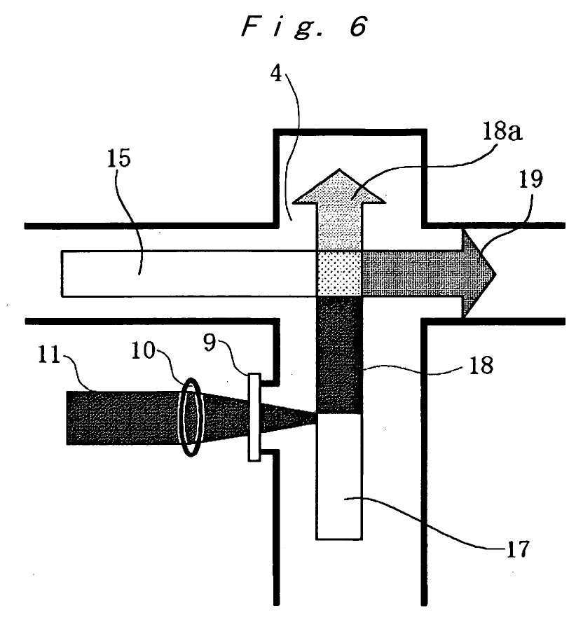

The operation of the third embodiment of the present invention will be described below with reference to FIGS. 5 and 6. The multi-nuclear metal molecule is dissolved in an appropriate solvent such as tetrahydrofuran (THF), and then put into the capillary 12, as shown in FIG. 5. When differential evacuation is performed through the skimmer 13, the mist 15 of the multi-nuclear metal molecule solution is generated from the capillary outlet 14. The thus-generated mist 15 of the multi-nuclear metal molecule solution forms a molecular flow in a high vacuum state and goes straight.

On the other hand, the small crucible 2 is heated, to generate a vapor 17 of a highly-excited-electron-generation material. The vapor 17 of the highly excited electron generation material forms a molecular flow in a high vacuum state and goes straight. The thus-generated vapor 17 of the highly excited electron generation material is irradiated with light 11, to bring the vapor 17 of the highly excited electron generation material into a highly excited state. An enlarged view of the ionization chamber 4 is shown in FIG. 6.

As shown in FIG. 6, when the light 11 is converged by the convergent lens 10 and the vapor 17 of the highly excited electron generation material is irradiated with the resultant light 11 through the window 9, the vapor 17 of the highly excited electron generation material is brought into a highly excited state 18. In this case, as the light source of the light 11, for example, a dye laser or the like is preferably used. The mist 15 of the multi-nuclear metal molecule collides with an individual atom 18 in such a highly excited state in the ionization chamber 4, to receive electric charge, thereby to be ionized (reference numeral 18a in the figure denotes atoms the state of which returns to a ground state, and reference numeral 19 denotes the ionized multi-nuclear metal molecule).

Other configurations, operations and effects of the molecular beam apparatus according to this embodiment are almost the same as those of the molecular beam apparatus according to the first embodiment, and the description thereof is omitted.

### Fourth Embodiment

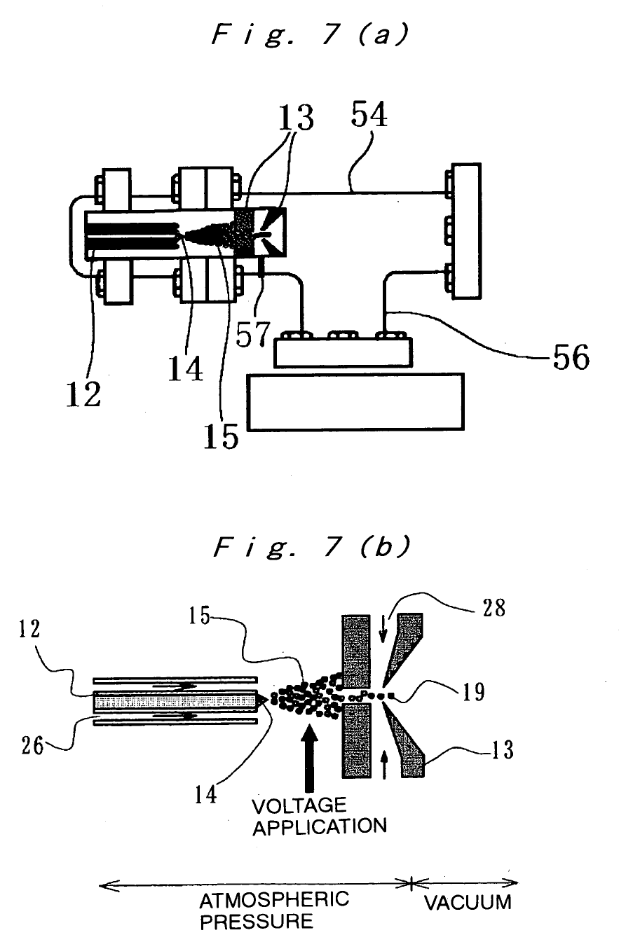

FIGS. 7(a) and 7(b) show the fourth embodiment of the present invention, and show an example in which the present invention is applied to a multi-nuclear metal molecule with no vapor pressure, similar to the third embodiment. FIG. 7(a) is a view showing an ionization device unit for the multi-nuclear metal molecule in the fourth embodiment, and FIG. 7(b) is an enlarged view explaining a capillary 12 and a skimmer 13 in FIG. 7(a).

In the ionization device unit for the multi-nuclear metal molecule, as shown in FIGS. 7(a) and 7(b), the capillary 12 is provided, and a multi-nuclear metal molecule solution is put into the capillary 12. A path 26 is provided on the outer periphery of the capillary 12, and an inert gas such as a nitrogen gas is put into the path 26. The skimmer 13 is provided near an outlet portion 14 of the capillary 12. As in the structure of the above third embodiment, a pipe 54 has evacuate pipes 56 and 57 formed thereon. A gas is evacuated from the pipes 56 and 57, to perform differential evacuation from the skimmer 13, thereby mist 15 of the multi-nuclear metal molecule solution is generated from the capillary outlet 14. A part where the capillary 12 is provided in the pipe 54 is set in an atmospheric-pressure state. A part extending from the position where the skimmer 13 is provided to the beam outlet is set in a vacuum state. Although not shown, a structure (the acceleration electrode, the convergence electrode, and the scanning electrode) near the beam outlet is the same as that in FIG. 1.

The operation of the fourth embodiment of the present invention will be described below. The multi-nuclear metal molecule is dissolved in an appropriate solvent such as tetrahydrofuran (THF), and then the resultant solution is introduced into the capillary 12. The inert gas such as a nitrogen gas is flowed out from the outer circumferential path 26 formed on the periphery of the capillary 12, thereby the mist 15 of the solution containing the multi-nuclear metal molecule is generated from the capillary outlet 14. The skimmer 13 for taking (picking up) a flow having a translational speed only in the axial direction of the mist 15 is provided in front of the capillary outlet 14 such that the skimmer 13 is slightly apart from the capillary outlet 14. A high voltage of several kV is applied across the capillary outlet 14 and the skimmer 13, to make it possible to decrease the particle diameter of the mist 15 of the multi-nuclear metal molecule and to give electric charge to the mist 15.

On the other hand, when a dried nitrogen gas is sprayed, under a reduced pressure, from the outer periphery of a circumferential path 28 formed in the skimmer 13, to vaporize the solvent, the multi-nuclear metal molecular ion 19 in a vapor phase can be obtained. The ionized multi-nuclear metal molecule is accelerated and converged in the same manner as in the first, second, and third embodiments, and then flowed out as a beam.

Other configurations, operations and effects of the molecular beam apparatus according to this embodiment are almost the same as those of the molecular beam apparatus according to the first embodiment, and the description thereof is omitted.

### Fifth Embodiment

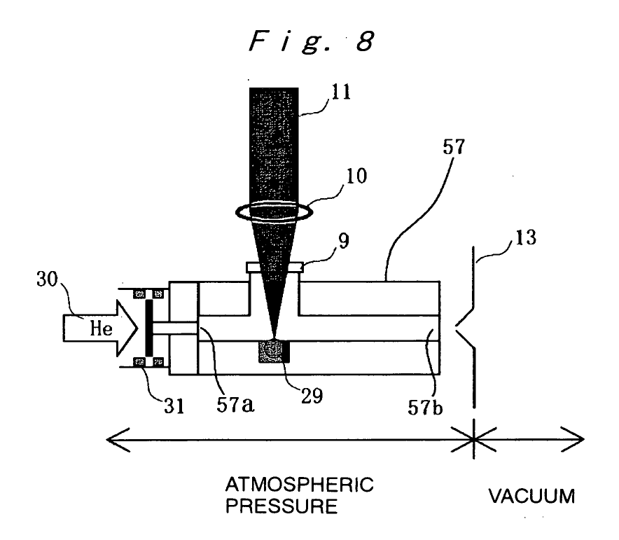

FIG. 8 shows an ionization device unit for a multi-nuclear metal molecule in a fifth embodiment of the present invention, and shows an example in which the present invention is applied to a multi-nuclear metal molecule with no vapor pressure such as Rh₆(CO)₁₆ or a multi-nuclear metal molecule having a low vapor pressure.

This embodiment can be carried out, using a method called a Matrix Assisted Laser Desorption Ionization (MALDI) method. According to the MALDI method, a trace amount of sample is uniformly dispersed in a matrix of solid or liquid which specifically absorbs the wavelength of an ultraviolet laser, and then the resultant sample is irradiated with a laser beam, thereby the sample is ionized.

In the molecular beam apparatus shown in FIG. 8, a matrix 29 in which a multi-nuclear metal molecule is dispersed is provided in a pipe 57. The matrix 29 is irradiated with light 11 converged by a convergent lens 10, through a window 9 provided on the pipe 57. An inert gas inlet 57a is formed at one end of the pipe 57, and an outlet 57b for the multi-nuclear metal molecule to be ionized is provided at the other end of the pipe 57. A skimmer 13 for supplying the ionized multi-nuclear metal molecule into the vacuum system is provided near the outlet 57b. An atmospheric-pressure state is set in the pipe 57, and a part extending from the position where the skimmer 13 is provided to the beam outlet is set in a vacuum state. Although not shown, a structure (the acceleration electrode, the convergence electrode, and the scanning electrode) near the beam outlet is the same as that in FIG. 1.

The operation of the fifth embodiment of the present invention will be described below. A powder of the multi-nuclear metal molecule is dispersed in the matrix 29 such as liquid paraffin, to set the powder. A strong laser light 11 is converged by a convergent lens 10, and then the matrix 29 such as liquid paraffin in which the powder of the multi-nuclear metal molecule has been dispersed is irradiated with the resultant light through the window 9. At this time, as a light source of the light 11, for example, a YAG laser or the like is preferably used. This irradiation causes ablation together with the matrix, to vaporize and ionize the multi-nuclear metal molecule at once. An inert gas (e.g., helium gas) 30 is emitted by a pulse valve 31 provided on an inert gas inlet 57a, synchronizing the timing with the multi-nuclear metal molecular ion, and the multi-nuclear metal molecular ion is supplied into the vacuum system through the skimmer 13. Thereafter, the multi-nuclear metal molecular ion is accelerated and converged, and then flowed out as a beam.

According to the molecular beam apparatus of the present invention, by using a chemically stable multi-nuclear metal molecule such as a metal cluster complex, a beam of cluster uniform in size can be stably obtained. Further, the molecular beam apparatus of the present invention can realize reduction in apparatus size.

The present invention will be described in more detail based on examples given below, but the invention is not meant to be limited by these.

### EXAMPLES

A cluster ion beam was generated, using the apparatus, as shown in FIG. 8.

A multi-nuclear metal molecule Rh₆(CO)₁₆ having a low vapor pressure was dispersed in a matrix (liquid paraffin), and the matrix was set in the apparatus, as shown in FIG. 8. The matrix was irradiated with a laser beam, using the third harmonic component wave (355 nm, pulse) of a Nd:YAG laser, to vaporize and simultaneously ionize the multi-nuclear metal molecule.

Then, a helium gas was emitted by the pulse valve 31 provided on the inert gas inlet 57a, synchronizing the timing with the multi-nuclear metal molecular ion. The multi-nuclear metal molecular ion was supplied into the vacuum system through the skimmer 13, accelerated, and converged. Thereafter, the multi-nuclear metal molecular ion was possible to be flowed out as a beam.

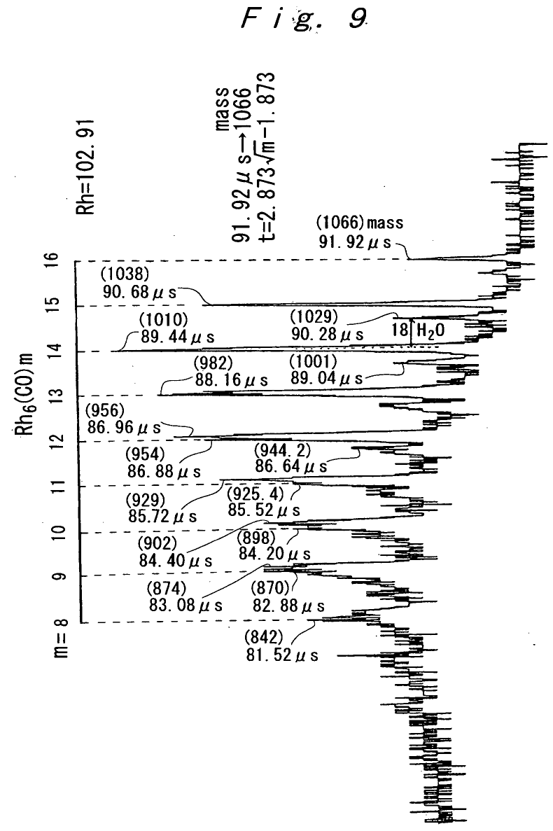

Further, mass spectrometry for the vapor of the multi-nuclear metal molecule was performed. The result of the mass spectrometry is shown in FIG. 9. As is apparent from FIG. 9, from Rh₆(CO)₁₆ having a mass number of 1066, peaks can be observed every 28 corresponding to CO serving as a ligand. That is, the multi-nuclear metal molecules from which an integer number of the ligand(s) was removed can be simultaneously observed. From this fact, it is understood that metal structure serving as a basic bone structure of the multi-nuclear metal molecule is kept even after the ligand(s) is removed in ionization. In other words, it is understood that the multi-nuclear metal molecule is ionized, while keeping the metal structure; and that a beam of the cluster uniform in size can be stably obtained.

### INDUSTRIAL APPLICABILITY

According to the molecular beam apparatus of the present invention, by using a chemically stable multi-nuclear metal molecule such as a metal cluster complex, a beam of cluster uniform in size can be stably obtained. Further, the molecular beam apparatus of the present invention can realize reduction in apparatus size.

Therefore, the molecular beam apparatus of the present invention is useful for ultra-precision machining or modification of a substrate. Further, the molecular beam apparatus of the present invention can also be used in preparation of a thin film obtained by depositing a cluster on a substrate.

Having described our invention as related to the present embodiments, it is our intention that the invention not be limited by any of the details of the description, unless otherwise specified, but rather be construed broadly within its spirit and scope as set out in the accompanying claims.

1. A multi-nuclear metal molecular beam apparatus, which generates an ion beam by using a multi-nuclear metal molecule.

2. The multi-nuclear metal molecular beam apparatus as claimed in claim 1, wherein the multi-nuclear metal molecule that is vaporized or atomized, is ionized.

3. The multi-nuclear metal molecular beam apparatus as claimed in claim 2, wherein the multi-nuclear metal molecule that is vaporized or atomized, is ionized by electron impact.

4. The multi-nuclear metal molecular beam apparatus as claimed in claim 2, wherein the multi-nuclear metal molecule that is vaporized or atomized, is ionized by light irradiation.

5. The multi-nuclear metal molecular beam apparatus as claimed in claim 2, wherein the multi-nuclear metal molecule that is vaporized or atomized, is ionized by plasma.

6. The multi-nuclear metal molecular beam apparatus as claimed in claim 2, wherein the multi-nuclear metal molecule that is vaporized or atomized, is ionized by an electric field.

7. The multi-nuclear metal molecular beam apparatus as claimed in claim 2, wherein the multi-nuclear metal molecule that is vaporized or atomized, is ionized by electric charge exchange of highly-excited electrons.

8. The multi-nuclear metal molecular beam apparatus as claimed in claim 1, wherein the multi-nuclear metal molecule is vaporized and simultaneously ionized.

9. The multi-nuclear metal molecular beam apparatus as claimed in claim 8, wherein the multi-nuclear metal molecule is ionized by laser ablation.

10. The multi-nuclear metal molecular beam apparatus as claimed in any one of claims 1 to 7, wherein the multi-nuclear metal molecule is dissolved in a solvent and generated as mist, and the mist of the multi-nuclear metal molecule is given an electric charge, to be ionized.

11. A multi-nuclear metal molecular beam apparatus, comprising:
vaporization means of a multi-nuclear metal molecule;
ionization means;
acceleration means;
convergence means; and
scanning means.
